(19) United States
(12) Patent Application Publication
(10) Pub. No.: US 2006/0133052 A1
(43) Pub. Date: Jun. 22, 2006

(54) Foldable electronic device having a flexible hinge mechanism

(76) Inventors: Roger W. Harmon, Crystal Lake, IL (US); James F. Caruso, Wilmette, IL (US); Lavanya Uppugonduri, Vernon Hills, IL (US)

Correspondence Address: MOTOROLA INC, 600 NORTH US HIGHWAY 45, ROOM AS437, LIBERTYVILLE, IL, 60048-5343, US

(21) Appl. No.: 11/015,457

(22) Filed: Dec. 17, 2004

(51) Int. Cl. H05K 5/00

(52) U.S. Cl. 361/752; 361/759; 361/749

(57) ABSTRACT

A foldable electronic device (100) includes a flexible hinge mechanism for enabling the opening and closing of the first housing element (102) and the second housing element (104). The flexible hinge mechanism includes a flexible hinge element (106), a drag link (108) and a flexible connection strip (506). The flexible hinge element connects the two housing elements and is elastic in nature. The drag link also connecting the two housing elements and limits an opening angle between the two housing elements to an angle less than 180 degrees. The flexible connection strip is routed along the length of the flexible hinge element and connects electrical circuits in the two housing elements for exchange of signals.

### FIELD OF THE INVENTION

This invention relates in general to hinge mechanisms, and more specifically to flexible hinge mechanisms for use in foldable electronic devices.

### BACKGROUND OF THE INVENTION

With the increasing popularity of electronic devices, a large number of mobile electronic devices such as mobile phones, pagers, personal digital assistants and the like have been introduced in the market. These devices are designed in small sizes so that users can carry them easily. However, their small size reduces the area available for keys and displays on the mobile electronic device. To solve this problem, devices with hinge structures were developed. These devices have hinges, so that they can be folded while not in use.

The foldable electronic devices generally have two housings, which are connected through a hinge mechanism. The hinge mechanisms also provide a space for routing electrical connections between the two housings. Various designs have been provided in the prior art for the foldable electronic devices and the hinge mechanisms. In one of the designs, a foldable electronic device having two housings are connected using a hinge mechanism, which allows the two housings to rotate, relative to each other. The hinge mechanism also houses a connector to establish an electrical connection between the two casings.

Apart from electronic devices, hinge mechanisms are also used in many consumer products such as money clips, boxes, etc. A hinge, for connecting a lid to a box, generally includes a flexible web to connect the lid to the box, a mounting means to attach the lid to the hinge, and a pinching means to attach the hinge to the box.

One or more of the hinge mechanisms described above suffer from one or more of the following limitations. First, the routing of electrical connection through the hinge mechanisms in electronic devices is complicated, leading to an increase in the cost of manufacturing the electronic device. Second, due to a number of openings around the hinge area, such electronic devices are not water resistant.

### BRIEF DESCRIPTION OF THE DRAWINGS

Various embodiments will hereinafter be described in conjunction with the appended drawings provided to illustrate and not to limit the invention, wherein like designations denote like elements, and in which:

FIG. 1 is a view of a foldable electronic device including a flexible hinge mechanism, in accordance with a first embodiment.

FIG. 2 is a side view of the foldable electronic device in an open position, in accordance with the first embodiment.

FIG. 3 is a side view of the foldable electronic device in a closed position, in accordance with the first embodiment.

FIG. 4 is a side view of a flexible hinge element, in accordance with the first embodiment.

FIG. 5 is cross-sectional view of a flexible hinge element through cut line 5-5 of FIG. 4, in accordance with the first embodiment.

FIG. 6 is a plot showing the variation in torque generated by a flexible hinge element, with its rotation from a relaxed position, in accordance with the first embodiment.

FIG. 7 is a plot showing the variation in torque generated by a preloaded flexible hinge element, in accordance with a second embodiment.

FIG. 8 is a view of a foldable electronic device including a flexible hinge mechanism, in accordance with a third embodiment.

FIG. 9 shows a foldable electronic device in a closed position, in accordance with a fourth embodiment.

FIG. 10 is a cross-sectional view of the flexible hinge element through cut line 10-10 of FIG. 9, in accordance with the fourth embodiment.

### DETAILED DESCRIPTION OF THE EMBODIMENTS

A foldable electronic device has a flexible hinge mechanism for connecting two housing elements. The flexible hinge mechanism includes a flexible hinge element and a drag link. The flexible hinge element is elastic in nature and is attached to the two housing elements. The drag link also connects the two housing elements and holds the housing elements in a predefined open position. The flexible hinge mechanism further includes a flexible connection strip for connecting electrical circuits in the two housing elements.

The instant disclosure is provided to further explain, in an enabling manner, the best modes of making and using various embodiments, in accordance with the present invention. The disclosure intends to enhance the perception and appreciation of the inventive principles and advantages thereof, rather than to limit in any manner the invention. The invention is defined solely by the appended claims, including any amendments made during the pendency of this application, and all the equivalents of the claims, as issued.

It is further understood that the relational terms, if any, such as first and second, top and bottom, and the like, are used solely to distinguish one entity or action from another, without necessarily requiring or implying any actual relationship or order between such entities or actions.

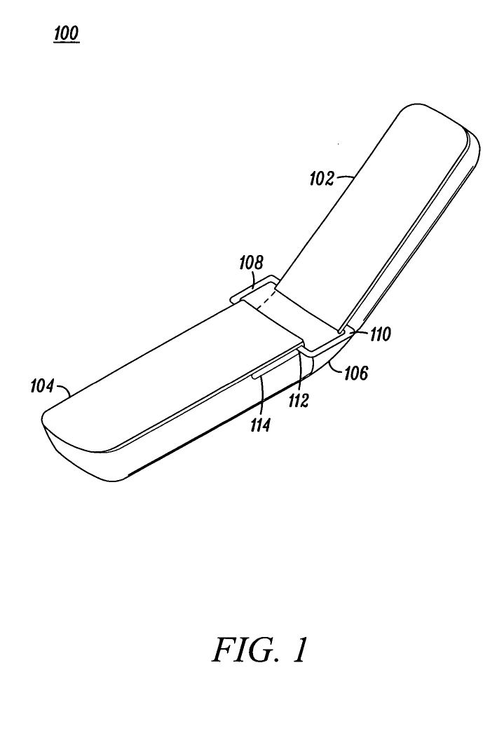

FIG. 1 shows a foldable electronic device 100 including a flexible hinge mechanism, in accordance with a first embodiment. Examples of the foldable electronic device 100 include devices such as mobile phones, pagers, personal digital assistants, calculators, etc. The foldable electronic device 100 includes a first housing element 102, a second housing element 104, a flexible hinge element 106, and a drag link 108. The foldable electronic device 100 has an open position when the first housing element 102 is at an angle less than 180 degrees, and more than zero degrees with the second housing element 104. This angle is the opening angle of the foldable electronic device 100. The foldable electronic device 100 has a closed position when the first housing element 102 is placed on top of the second housing element 104.

The flexible hinge element 106 connects the first housing element 102 and the second housing element 104 and is attached to them by means such as screws, adhesives, laser welding, ultrasonic welding, heat stakes, assembled pins, snaps or any combination of the above-mentioned methods. The flexible hinge element 106 is elastic in nature and has a relaxed position when the opening angle of the foldable electronic device 100 is 180 degrees or greater. When rotated away from the relaxed position, a torque is generated in the flexible hinge element 106, in a direction opposite to the direction of rotation. As a result, the flexible hinge element 106 tends to force the foldable electronic device 100 back into the relaxed position. In accordance with an embodiment, the flexible hinge element 106 covers the entire width of the foldable electronic device 100, eliminating the openings around the hinge area. This makes the foldable electronic device 100 water resistant. In accordance with another embodiment, the width of the flexible hinge element 106 may be less than width of the foldable electronic device 100. The flexible hinge element 106 may have a plurality of strips, each strip being placed so as to cover at least a part of the width of the foldable electronic device 100, in accordance with yet another embodiment.

The drag link 108 connects the first housing element 102 to the second housing element 104. It is connected to one of the housing elements though a pivoting joint and to the other housing element through a sliding pivoting joint. In accordance with an embodiment, both the joints of the drag link 108 may be sliding pivoting joints. In accordance with another embodiment, drag link 108 is connected to the first housing element 102 through a pivoting joint at a first end 110, and to the second housing element 104 through a sliding pivoting joint at a second end 112. The second housing element 104 has a slot 114 that enables the second end 112 of the drag link 108 to slide inside it, thereby facilitating the opening and closing of the foldable electronic device 100. The length of the drag link 108 is such that it prevents the flexible hinge element 106 from getting in the relaxed position, thereby generally limiting the opening angle of the foldable electronic device 100 to an angle less than 180 degrees. In the implementation shown, the opening angle is maintained in the range of 150 degrees to 160 degrees. An opening angle of 150 degrees to 160 degrees increases the ease with which the foldable electronic device 100 can be operated. In order to control the opening velocity of the foldable electronic device 100, a dampening force, in the form of a spring, damper or frictional force, may be added to the drag link 108.

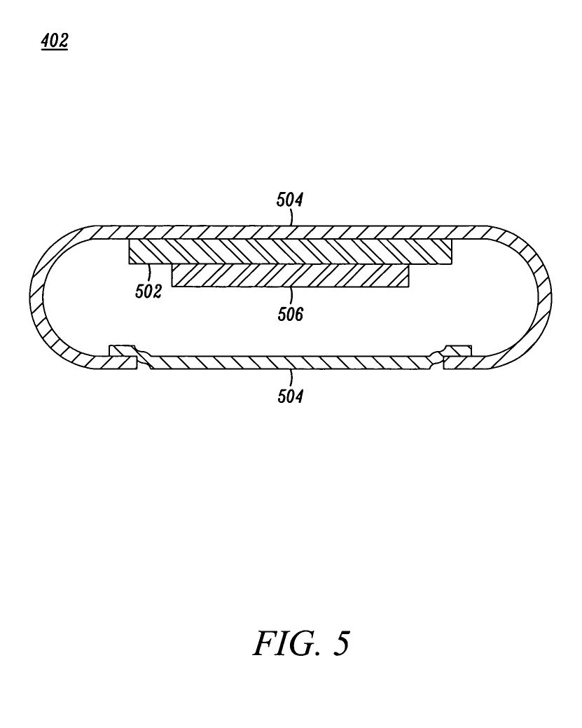

In accordance with an embodiment, the first housing element 102 and the second housing element 104 may contain electrical circuits inside them to support features, such as input keys for providing input to the foldable electronic device 100, and displays for output. The foldable electronic device 100 further includes a flexible connection strip for connecting electrical circuits in the first housing element 102 and the second housing element 104. The flexible connection strip is explained in detail in conjunction with FIG. 5.

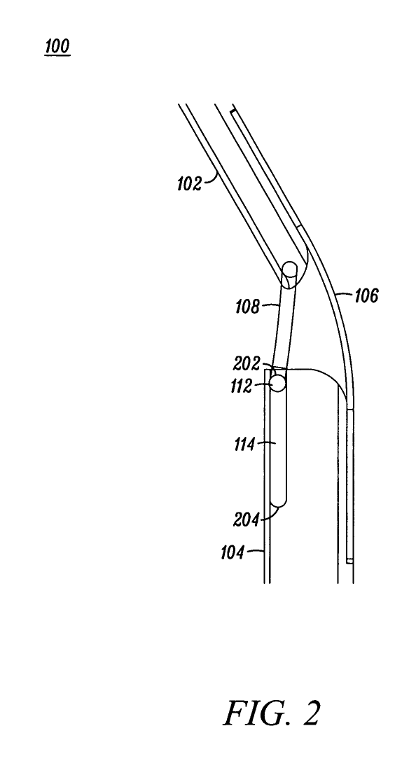

FIG. 2 shows a side view of the foldable electronic device 100 in an open position, in accordance with the first embodiment. The slot 114 has a first extreme end 202 and a second extreme end 204. In the open position, the second end 112 of the drag link 108 is at the first extreme end 202 in the slot 114. In this embodiment, the length of the drag link 108 is designed so as to limit the opening angle between the first housing element 102 and the second housing element 104 to an angle less than 180 degrees, and more particularly to an angle ranging from 150 degrees to 160 degrees.

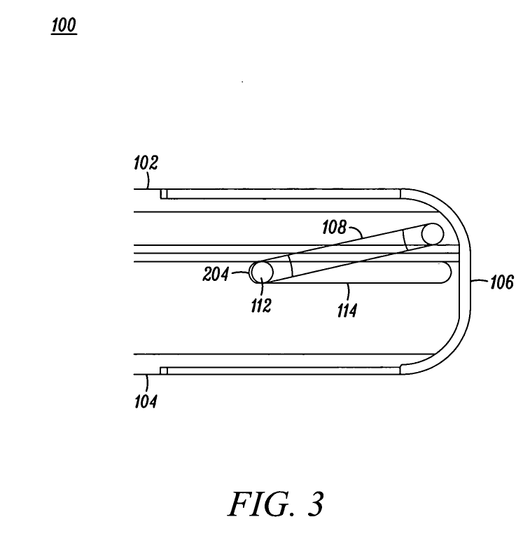

FIG. 3 shows a side view of the foldable electronic device 100 in a closed position, in accordance with the first embodiment. In the closed position, the first housing element 102 is placed over the second housing element 104. In this position, the second end 112 of the drag link 108 is at the second extreme end 204 in the slot 114.

The flexible hinge element 106 generates the maximum torque in the closed position, tending to force the foldable electronic device 100 to open unless constrained. The foldable electronic device 100 can be retained in the closed position using various methods. In one of the methods, a pair of magnets is placed inside the first housing element 102 and the second housing element 104, so that their force of attraction keeps the foldable electronic device 100 closed. In accordance with another embodiment, a magnet and a steel post or steel plate may be used instead of a pair of magnets. A snap and catch hook may also be used to achieve this purpose. The snap and catch hook can be mounted on two opposing ends of the flexible hinge element 106 and attached to each other or to the foldable electronic device 100. The length of the flexible hinge element 106 is designed so that the snap reaches the hook when the foldable electronic device 100 is in the closed position.

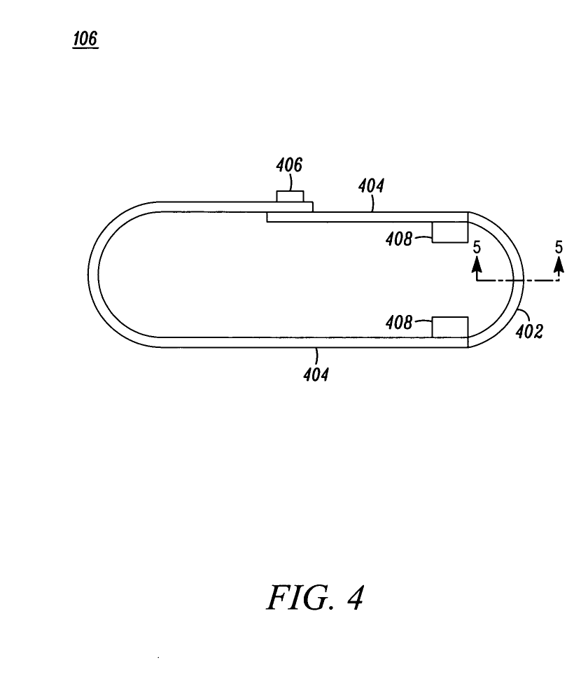

FIG. 4 shows a side view of the flexible hinge element 106, in accordance with the first embodiment. The flexible hinge element 106 includes a flexible portion 402 and a pair of straps 404. The flexible portion 402 is the elastic portion of the flexible hinge element 106. A torque is generated in this portion when the first housing element 102 is rotated away from the open position, as shown in FIG. 1. The flexible portion 402 is further explained in conjunction with FIG. 5. The pair of straps 404 is an extended portion of the flexible portion 402, and is used to attach the flexible portion 402 to the foldable electronic device 100 by means of screws or adhesives. Other non-metallic materials such as leather or textile may be used for manufacturing the pair of straps 404. The use of leather or textile material increases the appeal of the foldable electronic device 100. In accordance with another embodiment, non-metallic materials such as polyester, polycarbonate film, electro-luminescent film, etc. may be used to manufacture the pair of straps 404. The length of the pair of straps 404 depends on the method used to keep the foldable electronic device 100 in a closed position. If magnets are being used, the length of the pair of straps 404 may be kept equal to or less than the length of the housing elements 102 and 104. If a snap and catch hook 406 is being used, the length of the pair of straps 404 should be more than the length of the foldable electronic device 100, so that the snap reaches the hook in the closed position.

The flexible hinge element 106 may further have a pair of connectors 408 for connecting electrical circuits in the first housing element 102 to the electrical circuit in the second housing element 104. The connectors 408 are connected to a flexible connection strip placed inside the flexible hinge element 106. Electrical circuits in the first housing element 102 and the second housing element 104 are connected to each other to enable the flow of signals between the first housing element 102 and the second housing element 104.

FIG. 5 shows a cross-sectional view of flexible portion 402 through cut line 5-5 of FIG. 4, in accordance with the first embodiment. The flexible portion 402 includes a flexible hinge strip 502, a pair of covers 504, and a flexible connection strip 506. The flexible hinge strip 502 may include a single flexible strip or a number of flexible strips connected with each other. The flexible hinge element 106 is elastic in nature. It is in a relaxed position when the opening angle of the foldable electronic device 100 is 180 degrees or greater. Metallic materials such as stainless steel spring, nickel-titanium, etc. or non-metallic materials such as fiberglass, elastomer, etc. may be used as the material for the flexible hinge strip 502. The use of a metal band as the flexible hinge strip 502 improves the radio frequency ground, thereby providing part of an antenna system for mobile devices. The flexible hinge strip 502 is covered using the pair of covers 504. Leather or textile may be used as the material for the pair of covers 504. The pair of covers 504 allows the continuous use of leather or textile across the top, bottom and hinge areas of the foldable electronic device 100, thereby increasing design options. In accordance with an embodiment, the material used for manufacturing the pair of covers 504 may be the same as that used for manufacturing the pair of straps 404.

In accordance with another embodiment, different materials may be used for manufacturing the pair of covers 504. For example, one of the covers may be made from a decorative material, while the other may be manufactured from a thick layer of black polyester. Also, controlling the stiffness of the pair of covers 504 enables control of the opening velocity of the foldable electronic device 100. In accordance with an embodiment, a single cover covering at least one side of the flexible hinge strip 502 may be used instead of the pair of covers 504.

The flexible connection strip 506 connects electrical circuits in the first housing element 102 and the second housing element 104, as shown in FIG. 1 by means of the pair of connectors 408, as shown in FIG. 4. The flexible connection strip 506 is routed along the length of the flexible hinge strip 502 inside the flexible hinge element 106, and is covered by the pair of covers 504. The routing of the flexible connection strip 506 between the first housing element 102 and the second housing element 104 is simplified due to the large width of the flexible hinge strip 502. The simplified routing reduces the cost of the foldable electronic device 100.

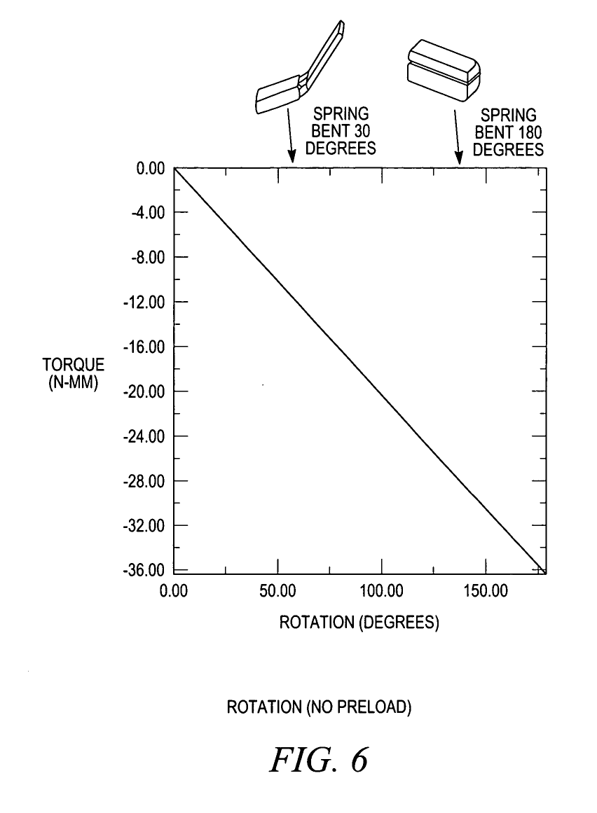

FIG. 6 depicts a plot showing the variation in torque generated by the flexible hinge strip 502, with its rotation from the relaxed position, in accordance with the first embodiment. In the relaxed position, the flexible hinge strip 502 is flat and generates no torque. The magnitude of the torque increases with its rotation, the maximum being at 180 degrees, i.e., when the foldable electronic device 100 is in a closed position. In this embodiment, the open position has an opening angle between the first housing element 102 and the second housing element 104 at an angle ranging from 150 degrees to 160 degrees, which results in the flexible hinge strip 502 rotating about 30 degrees which creates about −6 N-mm of torque. In this embodiment, the closed position has an opening angle between the first housing element 102 and the second housing element 104 at 0 degrees, which results in the flexible hinge strip 502 rotating about 180 degrees which creates almost −36 N-mm of torque.

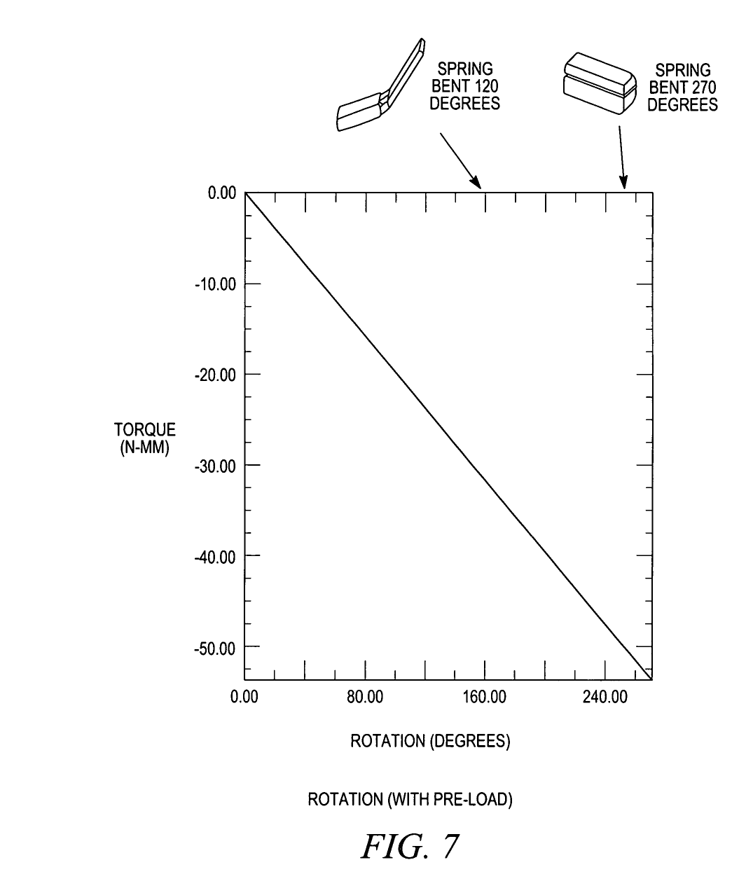

FIG. 7 depicts a plot showing the variation in torque generated by a preloaded flexible hinge strip 502, in accordance with a second embodiment. The flexible hinge strip 502 is preloaded in such a way that a predefined torque is generated when the foldable electronic device 100 is in the open position (shown in FIG. 1). With a −90 degree preload, when the flexible hinge strip 502 is bent 120 degrees, the foldable electronic device 100 is in the open position. In this embodiment, the open position has an opening angle between the first housing element 102 and the second housing element 104 at an angle ranging from 150 degrees to 160 degrees, which results in the flexible hinge strip 502 rotating about 120 degrees which creates about −25 N-mm of torque. In this embodiment, the closed position has an opening angle between the first housing element 102 and the second housing element 104 at an angle of 0 degrees, which results in the flexible hinge strip 502 rotating about 270 degrees which creates almost −53 N-mm of torque.

By changing the geometry of the flexible hinge strip 502, by (for example) halving the width of the flexible hinge strip 502, the range of torque from the open position to the closed position can be reduced to −12 N-mm to −27 N-mm, which results in less variation in torque than (for example) the flexible hinge strip 502 in FIG. 6. Preloading the flexible hinge strip 502 reduces the variation in torque from the open position to the closed position. The reduction in variation in the torque reduces the opening velocity of the foldable electronic device 100.

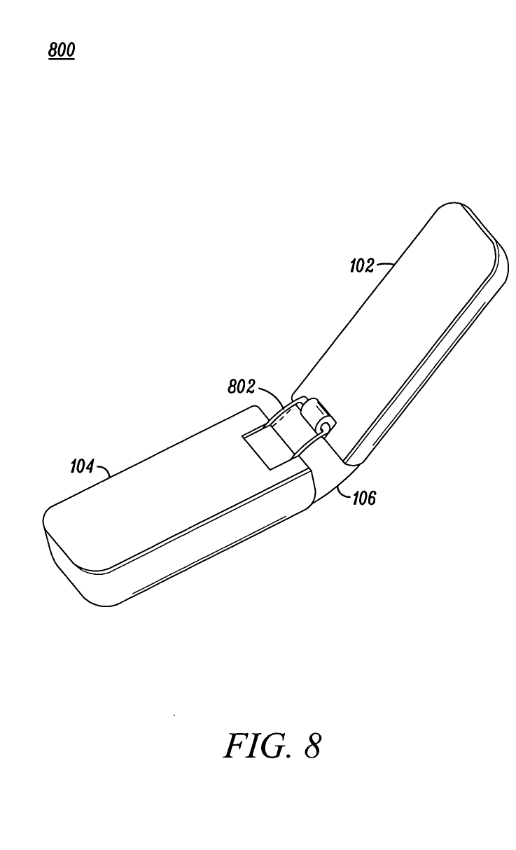

FIG. 8 shows a foldable electronic device 800 including a flexible hinge mechanism, in accordance with a third embodiment. The foldable electronic device 800 is similar to the foldable electronic device 100 in all respects except in the placement of a drag link 802. The drag link 802 is an internal link, i.e., it is placed along the internal surfaces of the second housing element 104. However, all the functionalities of the drag link 802 in the foldable electronic device 800 are the same as that of the drag link 108 in the foldable electronic device 100.

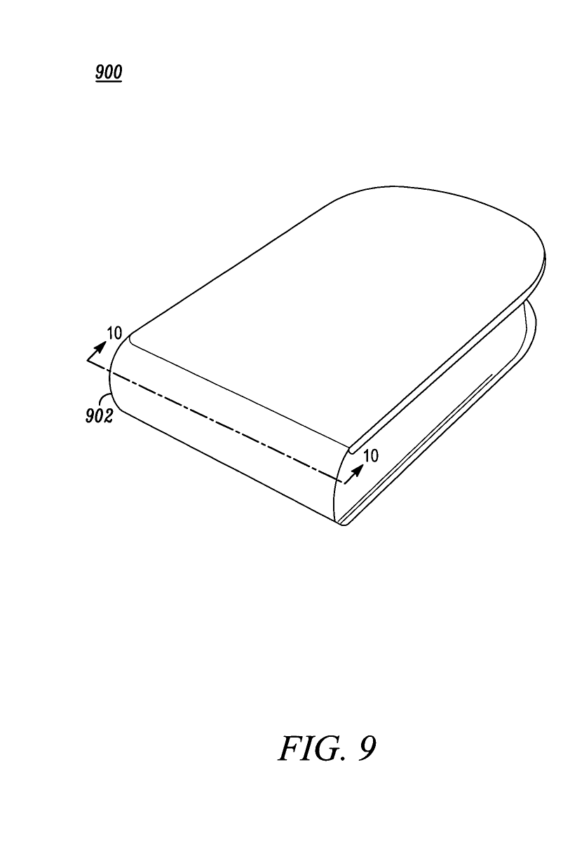

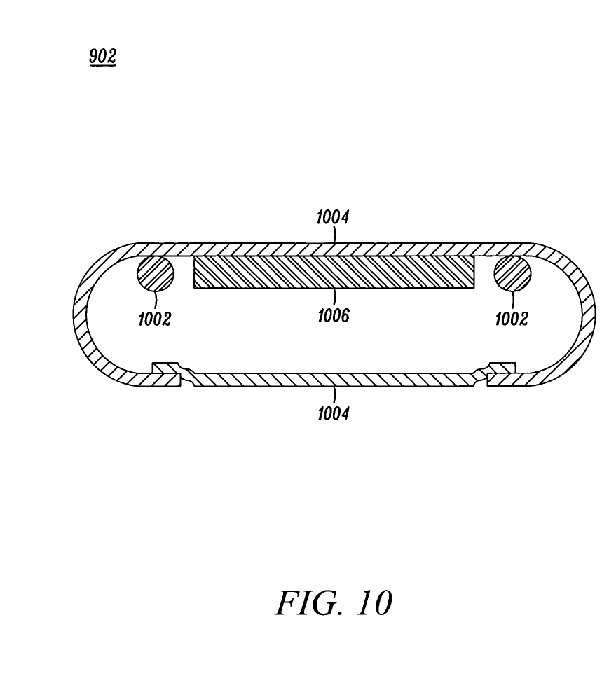

FIG. 9 shows a foldable electronic device 900 in a closed position, in accordance with a fourth embodiment. The foldable electronic device 900 is similar to the foldable electronic device 800 in all respects except the flexible hinge element 902. The flexible hinge element 902 is explained in conjunction with FIG. 10.

FIG. 10 is a cross-sectional view of the flexible hinge element 902 through cut line 10-10 of FIG. 9, in accordance with the fourth embodiment. The flexible hinge element 902 includes a flexible hinge strip 1002, a pair of covers 1004 and a flexible connection strip 1006. In accordance with an embodiment, the flexible hinge strip 1002 is a metal wire going around at least a part of the perimeter on the outside of the foldable electronic device 900. In accordance with another embodiment, the flexible hinge strip 1002 includes two or more metal wires placed along the perimeter of the foldable electronic device 900. The use of a metal wire as the flexible hinge strip 502 improves the radio frequency ground, thereby providing part of an antenna system for mobile devices. All other features of the flexible hinge strip 1002 are the same as that of the flexible hinge strip 502. The features of the pair of covers 1004 are also the same as that of the pair of covers 504. In accordance with an embodiment, a single cover may also be used to cover the flexible hinge strip 1002 from at least one side. The pair of cover 1004 is placed along the flexible connection strip 1006. All other functionalities of the flexible connection strip 1006 are the same as that of the flexible connection strip 506.

In an exemplary embodiment, the thickness of the first housing element 102 and the second housing element 104 is 10.78 mm and 11.88 mm. The length of the drag link 108 from the first end 110 to the second end 112 is 18.40 mm. The length of the flexible hinge element 106, lying between the first housing element 102 and the second housing element 104, is 34.98 mm. Further, in the open position, the flexible hinge element 106 forms an arc with a radius of 67.58 mm. In the closed position, it forms an arc with a radius of 11.33 mm.

While the dimensions have been stated above in connection with an specific embodiment, it is to be clearly understood that it is made only by way of example and not as a limitation on the scope of the invention

Therefore, it should be clear from the preceding disclosure that the invention provides a flexible hinge mechanism, which simplifies the complexity in routing the flexible connection strip between the housing elements, thereby reducing the cost of the flexible hinge mechanism. It further eliminates the openings around the hinge area, hence creating a potential for a water resistant foldable electronic device. It also allows the use of leather or textile across the top, bottom and hinge areas of the cell phone, increasing its appeal. Moreover, it increases the design flexibility.

This disclosure is intended to explain how to fashion and use various embodiments in accordance with the invention rather than to limit the true, intended, and fair scope and spirit thereof. The foregoing description is not intended to be exhaustive or to limit the invention to the precise forms disclosed. Modifications or variations are possible in light of the above teachings. The embodiments were chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

1. A foldable electronic device having a flexible hinge mechanism for enabling opening and closing of two housing elements, the foldable electronic device comprising:
a flexible hinge element, the flexible hinge element connecting the two housing elements, the flexible hinge element being elastic in nature, the flexible hinge element being in a relaxed position when an opening angle between the two housing elements is at least 180 degrees;
a drag link, the drag link connecting the two housing elements, the drag link limiting the opening angle between the two housing elements to an angle less than 180 degrees; and
a flexible connection strip, the flexible connection strip being routed along a length of the flexible hinge element, the flexible connection strip connecting electrical circuits in the two housing elements for exchange of signals.

2. The foldable electronic device according to claim 1 wherein the flexible hinge element comprises:
a flexible portion, the flexible portion being elastic in nature, the flexible portion being in a relaxed position when the opening angle between the two housing elements is at least 180 degrees; and
at least one strap, the at least one strap being an extended portion of the flexible portion, the at least one strap being used for attaching the flexible portion to the two housing elements.

3. The foldable electronic device according to claim 2 wherein the flexible portion comprises:
a flexible hinge strip, the flexible hinge strip being elastic in nature; and
a first cover covering the flexible hinge strip on at least one side.

4. The foldable electronic device according to claim 3 wherein the flexible hinge strip is manufactured from a metallic material.

5. The foldable electronic device according to claim 3 wherein the flexible hinge strip is manufactured from a non-metallic material.

6. The foldable electronic device according to claim 3 wherein the first cover is manufactured from a non-metallic material.

7. The foldable electronic device according to claim 3 wherein the flexible portion comprises:
a second cover for covering the flexible hinge strip on at least another side.

8. The foldable electronic device according to claim 7 wherein the second cover is manufactured from a non-metallic material.

9. The foldable electronic device according to claim 1 further comprising a snap and a catch hook for keeping the two housing elements in a closed position, the snap and the catch hook being mounted on either ends of the flexible hinge element, the snap and the catch hook being able to engage each other when the foldable electronic device is in a closed position.

10. The foldable electronic device according to claim 1 further comprising at least one magnet for keeping the two housing elements in a closed position.

11. The foldable electronic device according to claim 10 further comprising a second magnet for keeping the two housing elements in a closed position.

12. The foldable electronic device according to claim 10 further comprising a metal piece to engage with the at least one magnet for keeping the two housing elements in a closed position.

13. A foldable electronic device according to claim 1 wherein the flexible hinge element comprises:
at least one metal wire, the at least one metal wire being elastic in nature, the at least one metal wire following at least a part of a perimeter of the two housing elements; and
a first cover covering the flexible hinge element on at least one side.

14. A foldable device having a flexible hinge mechanism for enabling opening and closing of two housing elements, the foldable device comprising:
a flexible hinge element, the flexible hinge element coupling the two housing elements, the flexible hinge element being elastic in nature, the flexible hinge element being in a relaxed position when an opening angle between the two housing elements is at least 180 degrees; and
a drag link, the drag link connecting the two housing elements, the drag link limiting the opening angle between the two housing elements to an angle less than 180 degrees.

15. The foldable device according to claim 14 wherein the foldable device is an electronic device.

16. The foldable device according to claim 15 further comprises:
a flexible connection strip, the flexible connection strip being routed along a length of the flexible hinge element, the flexible connection strip connecting electrical circuits in the two housing elements for exchange of signals.

17. The foldable device according to claim 14 further comprising a snap and a catch hook for keeping the two housing elements in a closed position, the snap and the catch hook being mounted on either ends of the flexible hinge element, the snap and the catch hook being able to engage each other when the foldable device is in a closed position.

18. The foldable device according to claim 14 further comprising at least one magnet for keeping the two housing elements in a closed position.

19. The foldable device according to claim 18 further comprising a second magnet for keeping the two housing elements in a closed position.

20. The foldable device according to claim 18 further comprising a metal piece to engage with the at least one magnet for keeping the two housing elements in a closed position.
